(19) United States
(12) Patent Application Publication
(10) Pub. No.: US 2015/0130054 A1
(43) Pub. Date: May 14, 2015

(54) SEMICONDUCTOR PACKAGE STRUCTURE AND MANUFACTURING METHOD THEREOF

(71) Applicant: AMKOR TECHNOLOGY, INC., Chandler, AZ (US)

(72) Inventors: Jae Ung Lee, Seoul (KR); Byong Jin Kim, Gyeonggi-do (KR); Yoon Ki Namkung, Seoul (KR); Se Man Oh, Seoul (KR)

(21) Appl. No.: 14/538,018

(22) Filed: Nov. 11, 2014

(30) Foreign Application Priority Data
Nov. 13, 2013 (KR) 10-2013-013778

(51) Int. Cl. H01L 23/00; H01L 23/522

(52) U.S. Cl. CPC H01L 24/16; H01L 24/48; H01L 23/5226; H01L 2224/1601; H01L 2224/4801; H01L 2924/14
USPC 257/737; 257/774

(57) ABSTRACT

A semiconductor package and a method for manufacturing a semiconductor package that comprises a unit substrate, for example to which a semiconductor chip is attached, embedded in a base substrate on which a semiconductor device may be mounted. The base substrate may, for example, comprise vias between top and bottom surfaces thereof and/or vias between the top surface of the base substrate and a top surface of the unit substrate embedded within the base substrate.

### CROSS-REFERENCE TO RELATED APPLICATIONS/INCORPORATION BY REFERENCE

The present application makes reference to, claims priority to, and claims the benefit of Korean Patent Application No. 10-2013-013778, filed on Nov. 13, 2013 in the Korean Intellectual Property Office and titled “SEMICONDUCTOR PACKAGE STRUCTURE AND MANUFACTURING METHOD THEREOF”, the contents of which are hereby incorporated herein by reference, in their entirety.

### FEDERALLY SPONSORED RESEARCH OR DEVELOPMENT

[Not Applicable]

### SEQUENCE LISTING

[Not Applicable]

### MICROFICHE/COPYRIGHT REFERENCE

[Not Applicable]

### BACKGROUND

Present systems, methods and/or architectures for forming electronic packages with stacked components, for example having conventional interposers, are inadequate. Further limitations and disadvantages of conventional and traditional approaches will become apparent to one of skill in the art, through comparison of such approaches with the present invention as set forth in the remainder of the present application with reference to the drawings.

### BRIEF DESCRIPTION OF SEVERAL VIEWS OF THE DRAWINGS

The accompanying drawings are included to provide a further understanding of the present disclosure, and are incorporated in and constitute a part of this specification. The drawings illustrate exemplary embodiments of the present disclosure and, together with the description, serve to explain various principles of the present disclosure. In the drawings:

FIG. 1 illustrates a cross-sectional view of a semiconductor package structure, in accordance with various aspects of the present disclosure;

FIG. 2 illustrates a cross-sectional view of a semiconductor package structure, in accordance with various aspects of the present disclosure; and

FIGS. 3A to 3F illustrate example cross-sectional views sequentially showing a method of manufacturing a semiconductor package structure, in accordance with various aspects of the present disclosure.

### SUMMARY

Various aspects of this disclosure provide a semiconductor package structure and a manufacturing method. As a non-limiting example, various aspects of this disclosure provide a semiconductor package and a method for manufacturing a semiconductor package that comprises a unit substrate, for example to which a semiconductor chip is attached, embedded in a base substrate on which a semiconductor device may be mounted. The base substrate may, for example, comprise vias between top and bottom surfaces thereof and/or vias between the top surface of the base substrate and a top surface of the unit substrate embedded within the base substrate.

### DETAILED DESCRIPTION OF VARIOUS ASPECTS OF THE INVENTION

The following discussion presents various aspects of the present disclosure by providing various examples thereof. Such examples are non-limiting, and thus the scope of various aspects of the present disclosure should not necessarily be limited by any particular characteristics of the provided examples. In the following discussion, the phrases “for example,” “e.g.,” and “exemplary” are non-limiting and are generally synonymous with “by way of example and not limitation,” “for example and not limitation,” and the like.

The following discussion may at times utilize the phrase “A and/or B.” Such phrase should be understood to mean just A, or just B, or both A and B. Similarly, the phrase “A, B, and/or C” should be understood to mean just A, just B, just C, A and B, A and C, B and C, or all of A and B and C.

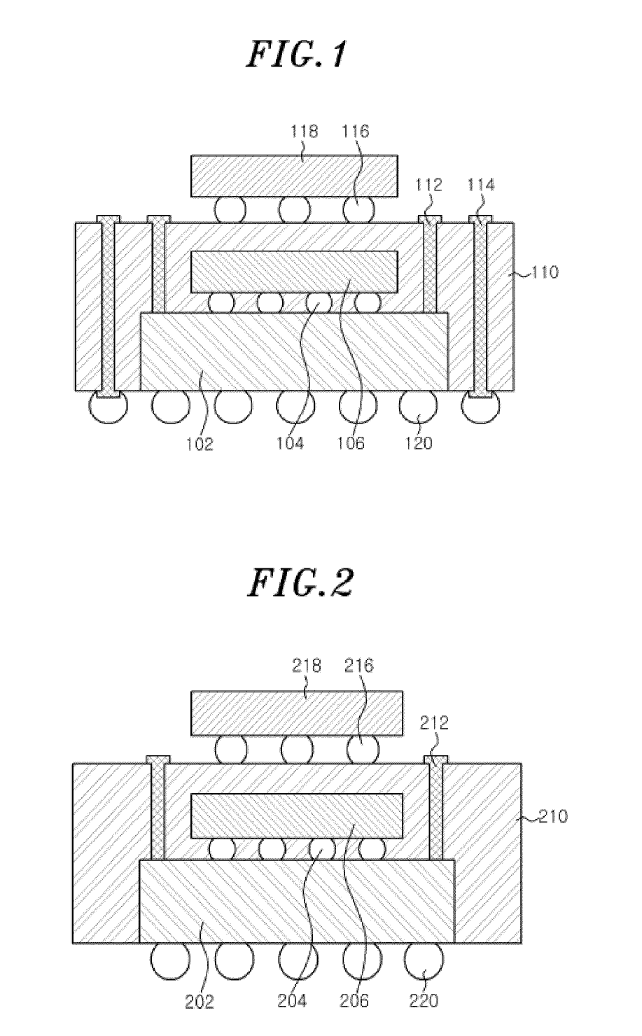

Turning first to FIG. 1, such figure illustrates a cross-sectional view of a semiconductor package structure, in accordance with various aspects of the present disclosure.

The semiconductor package structure may, for example, comprise a unit substrate 102 that is embedded in an inner portion of a base substrate 110, the unit substrate 102 having at least one semiconductor chip 106 attached on the top surface (or upper portion) thereof via a first conductive bump 104. The semiconductor package structure may further comprise a semiconductor device 118 formed on or attached to the top surface of the base substrate 110 and be electrically connected to the semiconductor chip 106 via a second conductive bump 116.

The unit substrate 102 may, for example, comprise characteristics of any of a variety of substrate types. For example, the unit substrate 102 may comprise characteristics of a packaging substrate, a printed wire board substrate, a laminate substrate, etc. The unit substrate 102 may, for example, comprise a top surface, a bottom surface, and side surfaces connecting the top and bottom surfaces. Note that the terms “top,” “bottom,” and “side” are selected for illustrated clarity to match the orientation of FIG. 1, and other figures discussed herein, when oriented up-right. Such terms may, for example, specify relative relationships between each other, but are otherwise non-limiting in an absolute sense.

The semiconductor chip 106 may, for example, comprise a semiconductor die (e.g., a logic die, processor die, memory die, system-on-a-chip die, etc.). The semiconductor chip 106 may, for example, comprise a top surface, a bottom surface, and side surfaces connecting the top and bottom surfaces. The bottom surface of the semiconductor chip 106 may, for example, be coupled to the top surface of the unit substrate 102. The bottom surface of the semiconductor chip 106 may, for example, comprise an active or inactive surface of the semiconductor chip 106. In the example configuration shown in FIG. 1, the bottom surface of the semiconductor chip 106 is an active surface of the semiconductor chip 106, which is mechanically and electrically coupled to the top surface of the unit substrate 102 with conductive bumps (e.g., solder bumps or balls, metal posts or pillars, metal pins or wires, etc.) in a flip-chip configuration. Note, however, that the semiconductor chip 106 may be coupled to the unit substrate 102 in any of a variety of manners without departing from the spirit and scope of this disclosure. For example, the bottom surface of the semiconductor chip 106 may be an inactive surface of the semiconductor chip 106 that is mechanically coupled to the top surface of the unit substrate 102 with an adhesive, and the top surface of the semiconductor chip 106 may be an active surface of the semiconductor chip 106 that is electrically coupled to the top surface of the unit substrate 102 using wire bond structures, redistribution layer and via structures, etc. Though illustrated as a semiconductor die 106, element 106 may also, for example, comprise one or more semiconductor die, one or more integrated circuit packages, one more passive components, etc.

The base substrate 110 may be, for example, an embedded interposer of the unit substrate 102. For example, the base substrate 110 may provide for connection redistribution (or rerouting), for example to provide connectivity between the unit substrate 102 and the top of the base substrate, to provide connectivity between the semiconductor die 106 to the top of the base substrate, to provide connectivity between the bottom of the base substrate 110 and the top of the base substrate 110, etc.

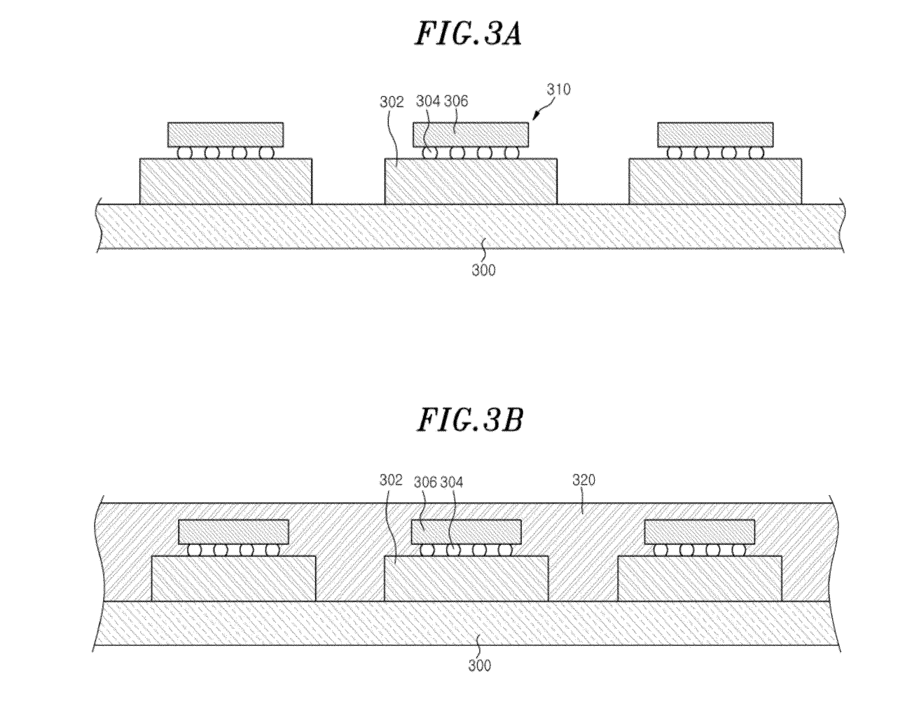

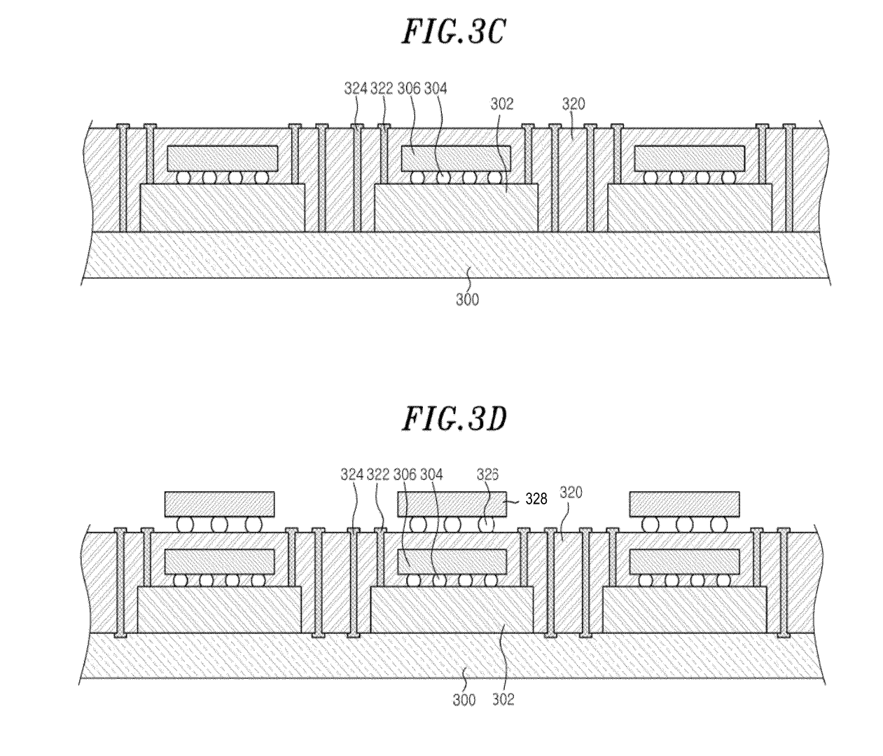

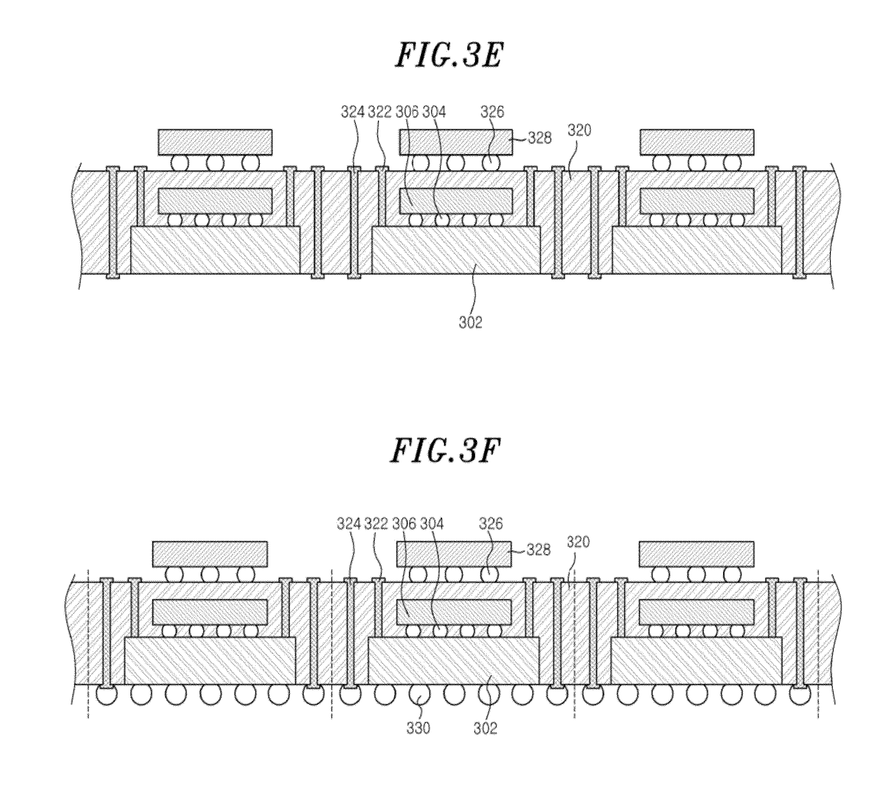

As will be discussed in more detail herein, for example in the discussion of FIG. 3, the base substrate 110 may, for example, be formed through a prepreg lamination process or the like. The base substrate 110 may be formed of any of a variety of materials. For example, the base substrate 110 may be formed of prepreg material (e.g., a fiberglass material impregnated with resin) that is deposited over the unit substrate 102 and/or semiconductor chip 106 in one or more deposition steps.

The semiconductor device 118 formed on (e.g., attached to) the base substrate 110 may be, for example, a semiconductor package or a semiconductor die such as a memory device, logic device, processor device, power supply device, etc. In order to electrically connect the semiconductor chip 106 and the semiconductor device 118 to each other, a plurality of circuit wirings (e.g., contacts, pads, metal wirings like traces or vias and the like, etc.) (not shown) may be formed on the base substrate therebetween. For example, in an example implementation, such circuit wirings may be formed (e.g., deposited and/or placed) on the top surface of the base substrate 110. For example, such circuit wirings may provide an electrical path from outside the horizontal (or lateral) footprint of the semiconductor chip 106 and/or semiconductor device 118 to inside the horizontal (or lateral) footprint of the semiconductor chip 106 and/or semiconductor device 118.

Each of the first and the second conductive bumps 104, 116 may, for example, comprise any one or more of a solder, a solder bump or ball, a conductive post or pillar, a conductive wire, etc. On the bottom surface (or a lower portion) of the unit substrate 102 and/or on the bottom surface (or a lower portion) of the base substrate 110, a plurality of board mounting bumps 120 (e.g., conductive bumps) may be formed on via contact pads (not shown), other contact pads, or the like. Such a board mounting bump 120 may, for example, comprise any one or more of a solder, a solder bump or ball, a conductive post or pillar, a conductive wire, etc.

The example semiconductor package structure may further, for example, comprise at least one through via 112 which functions as a conductive connecting member for extending and/or electrically connecting between the top surface (or upper portion) of the unit substrate 102 and the top surface (or upper portion) of the base substrate 110, and/or at least one through via 114 which functions as a conductive connecting member extending and/or electrically connecting between the top surface (or upper portion) and the bottom surface (or lower portion) of the base substrate 110. As shown in FIG. 1, such through vias 112 and/or 114 may, for example, extend directly vertically (i.e., without zig-zagging) between the top and/or bottom surfaces. Additionally, for example, such through vias 112 and/or 114 may each comprise a plurality of vertical segments coupled (or chained) to each other with horizontal segments (e.g., within the base substrate 110).

Turning next to FIG. 2, such figure illustrates a cross-sectional view of a semiconductor package structure, in accordance with various aspects of the present disclosure. The example package structure shown in FIG. 2 may, for example, share any or all characteristics with the example package structure shown in FIG. 1 and discussed herein. For example, items 202, 204, 206, 210, 212, 216, 218, and 220 of FIG. 2 may share any or all characteristics (e.g., structural and/or functional characteristics) with items 102, 104, 106, 110, 112, 116, 118, and 120 of FIG. 1, respectively. For illustrative clarity, the discussion of FIG. 2 will generally focus on the differences between the respective examples shown in FIG. 1 and FIG. 2.

Referring the example package structure shown in FIG. 2, unlike the previously described example of FIG. 1 that comprised a through via 114 that extended between and/or provided electrical connectivity between the top surface (or upper portion) of the base substrate 110 and the bottom surface (or lower portion) of the base substrate 110, the example semiconductor package structure shown in FIG. 2 does not have such a through via 114.

In other words, in accordance with various aspects of this disclosure, the semiconductor package structure may comprise at least one through via that extends between and/or provides electrical connectivity between the top surface (or upper portion) of the base substrate 110 and 210 and the bottom surface (or lower portion) of the base substrate 110 and 210, or might not comprise such a through via, depending on the implementation.

The discussion of FIG. 1 and FIG. 2 herein provided examples of a semiconductor package structure. The following discussion will generally focus on a method of manufacturing such example packages.

FIGS. 3A to 3F illustrate example cross-sectional views sequentially showing a method of manufacturing a semiconductor package structure, in accordance with various aspects of the present disclosure. The structural and/or functional elements illustrated in FIGS. 3A to 3F may share any or all characteristics with corresponding structural and/or functional elements shown in FIG. 1 and FIG. 2 discussed herein. For example, items 302, 304, 306, 320, 322, 326, 328, and 330 may share any or all characteristics (e.g., structural and/or functional characteristics) with items 202, 204, 206, 210, 212, 216, 218, and 220 of FIG. 2, respectively. Also for example, items 302, 304, 306, 320, 322, 324, 326, 328, and 330 may share any or all characteristics (e.g., structural and/or functional characteristics) with items 102, 104, 106, 110, 112, 114, 116, 118, and 120 of FIG. 1, respectively.

First, semiconductor chips 306 are attached to respective unit substrates 302 with first conductive bumps 304 to form, at least in part, respective substrate structures 310. Such substrate structures 310 may, for example be formed in a panel or wafer form or may be formed individually. In an example implementation in which the substrate structures 310 are formed in panel or wafer form, an individual substrate structure 310 may be formed from the panel or wafer by a singulation process (e.g., a cutting or sawing process).

Referring to FIG. 3A, a plurality of the substrate structures 310 may, for example, be aligned with target positions on a carrier 300 and then attached thereon, for example using an adhesive (e.g., an adhesive paste, an adhesive tape, etc.), a vacuum, etc. The carrier 300 may, for example, comprise any of a variety of materials (e.g., metal, glass, plastic, semiconductor, etc.). The carrier 300 may, for example, be re-usable or disposable.

Next, the substrate structures 310 (e.g., each comprising a unit substrate 302, and at least one semiconductor chip 306 coupled to the unit substrate 302, for example with conductive bumps 304) attached on the carrier 300 may be covered partially and/or completely with a base substrate material (e.g., a prepreg material). Such covering may, for example, be performed in any of a variety of manners (e.g., a flooding process, a cavity-molding process, a printing process, a focused deposition process, a prepreg lamination process etc.). A strip of base substrates 320 may thus be formed over the plurality of substrate structures 310 mounted on the carrier 300.

The base substrate 320 formation process may, for example, comprise one or more material deposition stages. For example, various aspects of this disclosure comprise forming the base substrate by, at least in part, successively performing the base substrate deposition process (e.g., a prepreg lamination process) a plurality of times. For example, the base substrate 320 formation process may comprise depositing a first portion of the base substrate material (e.g., between the substrate structures 310, unit substrates 302, conductive bumps 304, and/or semiconductor die 304), and then depositing a second portion of the base substrate material (e.g., over the top of the unit substrates 302 and/or semiconductor die 304).

In an example implementation, by performing a first prepreg lamination process, the base substrate material (e.g., prepreg material) is first deposited in a valley cavity which may exist with a relatively deep valley shape between each unit substrate 302 forming each substrate structure 310, and then, by performing a second prepreg lamination process, the plurality of the substrate structures 301, previously provided with the base substrate material between the unit substrates 302 can be covered or embedded completely with the base substrate material.

Depending, for example, on the viscosity of the base substrate material and/or the dimensions of cavities into which the base substrate material must flow, the base substrate material might not adequately fill the desired cavities in a single application. In such a scenario, a multiple-application process may beneficially provide for proper filling of the desired cavities, resulting in increased package reliability. Note that the base substrate material may or may not be present in the space between the unit substrate 302 and the semiconductor chip 306. In an example scenario in which the viscosity of the base substrate material will now allow for filling the space between the unit substrate 302 and the semiconductor chip 306, an additional process step (e.g., before or after mounting the substrate structures 310 to the carrier 300, between multiple base substrate material deposition stages, etc.) may comprise applying an underfill material between the unit substrate 302 and the semiconductor chip 306.

Following the base substrate material deposition process, a variety of types of circuit wiring processes (e.g., land and/or trace patterning, forming and/or filling via holes, etc.) may be performed. Land and/or trace patterning may, for example, comprise forming lands, traces, or other conductive structures on the top surface of the base substrate material (e.g., by masking and plating, print, etc.). Also for example, via hole forming may, for example, comprise mechanical drilling, laser drilling, etc.). Different types of via holes may, for example, be performed in a same or different manner. In an example scenario, a first set of vias (e.g., vias between the top and bottom surfaces of the base substrate 320) may be formed using a first drilling process (e.g., mechanical drilling), and a second set of vias (e.g., vias between the top of the base substrate 320 and the top of the unit substrate 302) may be formed using a second drilling process (e.g., laser drilling). Formed via holes may then, for example, be filled utilizing any of a variety of techniques (e.g., plating, conductive ball stacking, conductive paste filling, etc.). In an alternative example in which the base substrate material is applied in multiple stages, horizontal wiring features and/or vias may be formed on or in individual layers of the base material.

As shown in FIG. 3C as an example, a plurality of circuit wirings (e.g., contacts, pads, metal wirings, etc.) for electrically connecting between the semiconductor chip 306 formed on the unit substrate 302 and the semiconductor device to be formed on the base substrate 320 by a subsequent process, at least one through via 322 and at least one through via 324 are formed. Note that, as discussed herein for example in the discussion of FIG. 2, the through via 324 and/or through via 322 need not be formed.

After the formation of various types of circuit wiring (e.g., on and/or through the base substrate 320), semiconductor devices 328 may be attached to corresponding target positions above respective base substrates 320 of the strip of base substrate. For example, as shown in FIG. 3D, the semiconductor devices 328 may be attached to the corresponding target positions on the top surface (or upper portions) of the base substrates 320 (e.g., above the substrate structures 310) using second conductive bumps 326. The second conductive bumps 326 may, for example, comprise any one or more of solders, solder balls or bumps, conductive posts or pillars, conductive wires, etc. As discussed elsewhere herein the second conductive bumps 326 may, for example, be positioned directly above the horizontal (or lateral) footprint of the semiconductor chip 306 and/or the unit substrate 302. Also for example, the second conductive bumps 326 may be positioned directly above the base substrate 320 yet outside the horizontal footprint of the semiconductor chip 306 and/or the unit substrate 302.

After placement and/or attachment of the semiconductor devices 328, as shown in FIG. 3E as an example, a separation process may be performed to separate (isolate) the strip of base substrates 320 from the carrier 300. Such separation may, for example, be performed utilizing heat, pressure, light, shearing, grinding, etching, etc.

After separation of the strip of base substrates 320 from the carrier 300, ball dropping and reflowing processes may, for example, be performed as shown in FIG. 3F. For example, a plurality of board mounting bumps 330 (e.g., conductive bumps) may be formed, each corresponding to a respective contact pad (not shown) on the bottom surface (or lower portion) of a unit substrate 302 and/or to a respective contact pad (e.g., associated with a through via) on the bottom surface (or lower portion) of a base substrate 320. The board mounting bumps 330 may, for example, comprise, a solder, a solder bump or ball, a conductive post or pillar, a conductive wire, etc.

Finally, by carrying out a singulation process (e.g., a cutting or sawing process, etc.) of the strip of base substrates 320 along the cutting lines indicated by dotted lines in FIG. 3F, the semiconductor package structure may be completed. The package structure may, for example, comprise the base substrate 320 with a structure embedding the unit substrate 302 having the semiconductor chip 306 attached on the top surface thereof, and having the semiconductor device 328 attached on the base substrate via the second conductive bump 326. The package structure may, for example, comprise any or all characteristics of the example package structures shown in FIG. 1 and/or FIG. 2 and discussed herein. Additional processing steps for the example package structures may also be formed, for example repeating any one or more of the steps discussed herein, encapsulating the semiconductor device 328 and/or entire package structure, adding a lid, etc.

Various aspects of the present disclosure have been described in a way that the base substrate strip is separated from the carrier, and the board mounting bumps are formed on the lower portion of the separated base substrate strip, and then the base substrate strip is cut to individual semiconductor package structures. However, the disclosure is not limited thereto and may as well be carried out to manufacture the semiconductor package structures in a way that the base substrate strip is separated from the carrier, the separated base substrate strip is cut to individual semiconductor package structures, and then the board mounting bumps are formed on the lower portion of the individual semiconductor package structures.

In summary, various aspects of the present disclosure provide a semiconductor package and a method for manufacturing a semiconductor package that comprises a unit substrate, for example to which a semiconductor chip is attached, embedded in a base substrate on which a semiconductor device may be mounted. While the foregoing has been described with reference to certain aspects and embodiments, it will be understood by those skilled in the art that various changes may be made and equivalents may be substituted without departing from the scope of the disclosure. In addition, many modifications may be made to adapt a particular situation or material to the teachings of the disclosure without departing from its scope. Therefore, it is intended that the disclosure not be limited to the particular embodiment(s) disclosed, but that the disclosure will include all embodiments falling within the scope of the appended claims.

What is claimed is:

1. A semiconductor package comprising:
a unit substrate comprising a unit substrate top surface, a unit substrate bottom surface, and unit substrate side surfaces connecting the unit substrate top surface and the unit substrate bottom surface;
a semiconductor die comprising a die top surface, a die bottom surface, and die side surfaces connecting the die top surface and the die bottom surface, wherein the die bottom surface is coupled to the unit substrate top surface;
a base substrate comprising a base substrate top surface, a base substrate bottom surface, and base substrate side surfaces connecting the base substrate top surface and the base substrate bottom surface; and
a semiconductor device coupled to the base substrate top surface,
wherein the unit substrate and the semiconductor die are embedded in the base substrate, such that at least the top and side surfaces of the unit substrate and at least the side and top surfaces of the semiconductor die are contacted and surrounded by the base substrate.

2. The semiconductor package of claim 1, comprising a first electrically conductive via that extends between the unit substrate top surface and the base substrate top surface.

3. The semiconductor package of claim 2, comprising a second electrically conductive via that extends between the base substrate bottom surface and the base substrate top surface.

4. The semiconductor package of claim 3, wherein the second electrically conductive via comprises a vertical side extending completely through the base substrate, and the first electrically conductive via comprises a sloped non-vertical side extending through the base substrate.

5. The semiconductor package of claim 3, wherein the unit substrate bottom surface and the base substrate bottom surface are coplanar.

6. The semiconductor package of claim 5, further comprising a first electrically conductive bump attached to the unit substrate bottom surface and a second electrically conductive bump attached to the base substrate bottom surface.

7. The semiconductor package of claim 2, wherein the first electrically conductive via extends directly vertically between the unit substrate top surface and the base substrate top surface.

8. The semiconductor package of claim 1, wherein the semiconductor device is coupled to the base substrate top surface with at least a first conductive bump that is positioned directly above the semiconductor die.

9. The semiconductor package of claim 8, wherein the first conductive bump is electrically coupled to the die bottom surface.

10. The semiconductor package of claim 9, wherein the first conductive bump is electrically coupled to the die bottom surface through a first electrically conductive via that extends between the unit substrate top surface and the base substrate top surface.

11. The semiconductor package of claim 10, wherein the semiconductor device is coupled to the base substrate top surface with at least a second conductive bump that is positioned directly above the semiconductor die.

12. The semiconductor package of claim 11, wherein the second conductive bump is electrically coupled to the base substrate bottom surface through a second electrically conductive via that extends between the base substrate top surface and the base substrate bottom surface.

13. The semiconductor package of claim 10, wherein the first electrically conductive via runs directly vertically between the unit substrate top surface and the base substrate top surface.

14. The semiconductor package of claim 1, wherein the base substrate is formed of a prepreg material.

15. The semiconductor package of claim 1, wherein a portion of material of the base substrate is positioned between the die bottom surface and the unit substrate top surface.

16. The semiconductor package of claim 1, wherein the semiconductor device is one of a semiconductor package or a semiconductor die.

17. The semiconductor package of claim 1, wherein the die bottom surface is an active surface of the semiconductor die.

18. A semiconductor package comprising:
a unit substrate comprising a unit substrate top surface, a unit substrate bottom surface, and unit substrate side surfaces connecting the unit substrate top surface and the unit substrate bottom surface;
a semiconductor die comprising a die top surface, a die bottom surface, and die side surfaces connecting the die top surface and die bottom surface, wherein the die bottom surface is coupled to the unit substrate top surface;
a base substrate comprising a base substrate top surface, a base substrate bottom surface, and base substrate side surfaces connecting the base substrate top surface and the base substrate bottom surface; and
a semiconductor device coupled to the base substrate top surface,
wherein the unit substrate and the semiconductor die are embedded in the base substrate.

19. The semiconductor package of claim 18, further comprising:
a first electrically conductive via that extends between the unit substrate top surface and the base substrate top surface; and
a second electrically conductive via that extends between the base substrate bottom surface and the base substrate top surface.

20. A semiconductor package comprising:
a unit substrate comprising a unit substrate top surface, a unit substrate bottom surface, and unit substrate side surfaces connecting the unit substrate top surface and the unit substrate bottom surface;
a base substrate comprising a base substrate top surface, a base substrate bottom surface, and base substrate side surfaces connecting the base substrate top surface and the base substrate bottom surface, where the base substrate comprises a prepreg material; and
a semiconductor device coupled to the base substrate top surface,
wherein the unit substrate is embedded in the base substrate.
